(19) United States
(12) Patent Application Publication
(10) Pub. No.: US 2008/0076070 A1
(43) Pub. Date: Mar. 27, 2008

(54) Methods of Forming Fine Patterns In Integrated Circuits Using Atomic Layer Deposition

(75) Inventors: Cha-won Koh, Yongin-si (KR); Han-ku Cho, Seongnam-si (KR); Gi-sung Yeo, Seoul (KR); Yool Kang, Seongnam-si (KR); Ji-young Lee, Yongin-si (KR); Doo-youl Lee, Seongnam-si (KR)

Correspondence Address: MYERS BIGEL SIBLEY & SAJOVEC, PO BOX 37428, RALEIGH, NC, 27627, US

(73) Assignee: Samsung Electronics Co., Ltd.

(21) Appl. No.: 11/554,324

(22) Filed: Oct. 30, 2006

(30) Foreign Application Priority Data
Sep. 8, 2006 (KR) 10-2006-0086994

(51) Int. Cl. G03F 7/00

(52) U.S. Cl. 430/311

(57) ABSTRACT

A fine pattern is formed in an integrated circuit substrate, by forming a sacrificial pattern on the integrated circuit substrate. The sacrificial pattern includes tops and side walls. Atomic layer deposition is then performed to atomic layer deposit a mask material layer on the sacrificial pattern, including on the tops and the side walls thereof, and on the integrated circuit substrate therebetween. The mask material layer that was atomic layer deposited is then etched, to expose the top and the integrated circuit therebetween, such that a mask material pattern remains on the side walls. The sacrificial pattern is then removed, and the integrated circuit substrate is then etched through the mask material pattern that remains.

### CROSS-REFERENCE TO RELATED PATENT APPLICATION

This application claims the benefit under 35 USC §119 of Korean Patent Application No. 10-2006-0086994, filed on Sep. 8, 2006, the disclosure of which is hereby incorporated by reference in its entirety as if set forth fully herein.

### FIELD OF THE INVENTION

The present invention relates to integrated circuit fabrication methods and, more particularly, to methods of forming fine patterns in integrated circuit substrates.

### BACKGROUND OF THE INVENTION

Integrated circuits are widely used in many consumer, commercial and other applications. Fine patterns are generally formed in integrated circuits by photolithography. As the pattern resolution of the photolithography continues to improve, patterns having a finer line width can be formed. The pattern resolution (R) of a photolithography process can be expressed by Rayleigh's equation as follows:

R=k·(λ/NA); [Equation 1]

where λ denotes the wavelength of light emitted from an exposure light source, NA denotes the numerical aperture of a lens used in exposure equipment, and k denotes a process constant.

Referring to Equation 1, to improve the pattern resolution R, a light source emitting shorter-wavelength light or a lens having a larger NA may be used. For example, when a light source emitting short-wavelength light of about 193 nm is used, a fine pattern can be formed to a line width of about 80 nm or less. However, in this case, the manufacturing costs of devices may increase since exposure equipment using a short-wavelength light source may be expensive. The pattern resolution also can be increased using a lens having a large NA. However, in this case, there may be a limit in increasing the pattern resolution due to restrictions on exposure equipment.

With the increasing integration of integrated circuit devices, it may be desirable to form even finer line widths. According to a “double patterning” technology, a fine pattern having a line width smaller than several tens of nanometers can be formed in an integrated circuit device. In a process using the double patterning technology, patterning is performed twice to form a fine pattern with a fine line width. FIGS. 1A through 1F are cross-sectional views for explaining a conventional method of forming a fine pattern using the double patterning technology.

Referring to FIG. 1A, a lower layer 12 is formed on an integrated circuit substrate, such as a semiconductor substrate 10, and then a first mask material layer 14 and a second mask material layer 16 are sequentially formed on the lower layer 12. A first anti-reflective layer and a first photoresist layer are formed on the second mask material layer 16, and then the first anti-reflective layer and the first photoresist layer are patterned to form a first anti-reflective pattern 17a and a first photoresist pattern 18a.

Referring to FIG. 1B, the second mask material layer 16 is etched using the first photoresist pattern 18a to form a second mask pattern 16a. Referring to FIG. 1C, the first photoresist pattern 18a and the first anti-reflective pattern 17a are removed. A second anti-reflective layer and a second photoresist layer are formed on the second mask pattern 16a and the first mask material layer 14. Then, the second anti-reflective layer and the second photoresist layer are patterned to form a second anti-reflective pattern 17b and a second photoresist pattern 18b. The second anti-reflective pattern 17b and the second photoresist pattern 18b are formed on the first mask material layer 14 between the second mask pattern 16a. In this structure, the first mask material layer 14 is exposed between the second mask pattern 16a and the second photoresist pattern 18b.

Referring to FIG. 1D, the exposed first mask material layer 14 is etched using the second mask pattern 16a and the second photoresist pattern 18b as masks to form a first mask pattern 14a. Referring to FIG. 1E, the lower layer 12 is etched using the first mask pattern 14a and the second mask pattern 16b as masks to form a fine pattern 12a. Here, after the second photoresist pattern 18b and the second anti-reflective pattern 17b are removed, the lower layer 12 can be etched to form the fine pattern 12a. Referring to FIG. 1F, the first mask pattern 14a, the second mask pattern 16a, the second photoresist pattern 18b, and the second anti-reflective pattern 17b are removed. In this way, the fine pattern 12a is formed on the substrate 10.

In the above-described conventional method of forming a fine pattern, a fine pattern having a line width of 80 nm or less can be formed using a light source emitting 248 nm wavelength light, for example. However, when fine patterns having a line width of 40 nm or less are formed using this conventional method, a defective pattern such as a bridged pattern can occur. Referring again to FIG. 1C, since developer may not be sufficiently applied to the narrow gaps between the second mask pattern 16a and the second photoresist pattern 18b when the second photoresist pattern 18b is formed, the second ant-reflective layer may remain and cause a bridged pattern.

Furthermore, in the above-described conventional method, when the second mask pattern 16a and the first mask pattern 14a are misaligned with each other, a desired uniform space between the first and second mask patterns 14a and 14b may not be obtained. Therefore, a device having desired characteristics may not be obtained using the conventional method of forming a fine pattern. In addition, when the first mask pattern 14a and the second mask pattern 16a are misaligned with each other, and thus spaces in the first mask pattern 14a and the second mask pattern 16a are not uniform, the second anti-reflective layer 17b can remain in relatively narrow space openings in the first mask pattern 14a and the second mask pattern 16a, which may also cause pattern failure such as bridged patterns.

Moreover, since a photolithographic process should be repeated twice according to the conventional double patterning technology, it may be inconvenient and expensive to form a fine pattern. To address these problems, a spacer may be used in forming a fine pattern. In a method of forming a fine pattern using a spacer, a sacrificial insulation layer is deposited on a substrate, and then the deposited sacrificial insulation layer is patterned by photolithography to form a sacrificial insulation pattern. Next, a conductive layer is deposited on the sacrificial insulation pattern and on the substrate, and then the deposited conductive layer is patterned to form a conductive pattern on side walls of the sacrificial insulation pattern. Then, the sacrificial insulation pattern is removed, such that the conductive pattern can have a fine line width. However, in this method, the sacrificial insulation layer may be formed and patterned through deposition and etching processes. Therefore, the fine pattern forming method may be complicated. Furthermore, since the line width of the conductive pattern is determined by deposition uniformity of the conductive layer, it may be difficult to control the line width of the conductive pattern.

### SUMMARY OF THE INVENTION

Some embodiments of the present invention provide methods of forming a fine pattern in an integrated circuit substrate. A sacrificial pattern is formed on the integrated circuit substrate, the sacrificial pattern including tops and side walls. Atomic layer deposition is then performed to atomic layer deposit a mask material layer on the sacrificial pattern, including on the tops and the side walls thereof, and on the integrated circuit substrate therebetween. The mask material layer that was atomic layer deposited is then etched, to expose the top and the integrated circuit substrate therebetween, such that a mask material pattern remains on the side walls. The sacrificial pattern is then removed, and the integrated circuit substrate is then etched through the mask material pattern that remains. In some embodiments, the mask material layer comprises a nitride layer that is atomic layer deposited in a temperature range from about 30° C. and about 130° C. Moreover, in some embodiments, the sacrificial pattern comprises a sacrificial photoresist pattern.

Other embodiments of the present invention provide other methods of forming a fine pattern in an integrated circuit substrate. A first hard mask layer and a second hard mask layer are sequentially formed on the integrated circuit substrate, the second hard mask layer having an etch selectivity with respect to the first hard mask layer. A photoresist pattern is formed on the second hard mask layer, the photoresist pattern having a first line width and a first pitch. A mask material layer is formed on the photoresist pattern and the second hard mask layer by atomic layer deposition (ALD), the mask material layer including a material harder than the second hard mask layer. The mask material layer is etched until the photoresist pattern is exposed in order to form a mask pattern on side walls of the photoresist pattern, the mask pattern having a second pitch that is less than, and in some embodiments is half, the first pitch. The photoresist pattern is removed. The second hard mask layer is etched using the mask pattern to form a second hard mask pattern. The first hard mask layer is etched using the second hard mask pattern as a mask to form a first hard mask pattern. The integrated circuit substrate is then etched using the first hard mask pattern as a mask to form a fine pattern having same pitch as the second pitch.

These methods may further include forming an organic anti-reflective layer on the second hard mask layer prior to the forming of the photoresist pattern. The forming of the photoresist pattern may include coating a photoresist layer on the second hard mask layer, exposing and developing the photoresist layer to form the photoresist pattern with a second line width larger than the first line width and trimming the photoresist pattern to the first line width using O₂ plasma.

These embodiments may further include surface-treating the photoresist pattern to reduce a line width roughness (LWR) of the photoresist pattern prior to the forming of the mask material layer.

The first hard mask layer may include a spin-on-carbon (SOC) layer and/or a bottom photoresist layer, and the second hard mask layer may include a silicon-containing layer. Alternatively, the first hard mask layer may include an amorphous carbon layer (ACL), and the second hard mask layer may include an oxide layer. The mask material layer may include a nitride layer.

These methods may further include removing the mask pattern between the etching of the second hard mask layer and the etching of the first hard mask layer, removing the second hard mask pattern between the etching of the first hard mask layer and the etching of the substrate and removing the first hard mask pattern after the etching the substrate.

According to other embodiments of the present invention, an insulating layer is formed on an integrated circuit substrate. A first hard mask layer and a second hard mask layer are sequentially formed on the insulating layer, the second hard mask layer having an etch selectivity with respect to the first hard mask layer. A first photoresist pattern is formed on the second hard mask layer, the first photoresist pattern having a first line width and a first pitch. A mask material layer is formed on the first photoresist pattern and the second hard mask layer by ALD at a low temperature, the mask material layer including a material harder than the second hard mask layer. The mask material layer is etched until the first photoresist pattern is exposed in order to form a mask pattern on side walls of the first photoresist pattern, the mask pattern having a second pitch that is less than, and in some embodiments is half, the first pitch. A portion of the second hard mask layer is etched using the mask pattern. A second photoresist pattern is formed on the second hard mask layer, the second photoresist pattern partially exposing the etched portion of the second hard mask layer. The partially exposed portion of the second hard mask layer is etched using the second photoresist pattern until the first hard mask layer is exposed, so as to form a second hard mask pattern. The first hard mask layer is etched using the second hard mask pattern as a mask to form a first hard mask pattern. Then, the insulating layer is etched using the first hard mask pattern as a mask to form a contact hole.

These embodiments may further include removing the mask pattern between the etching of the portion of the second hard mask layer and the forming of the second photoresist pattern. These embodiments may further include forming a first organic anti-reflective layer on the second hard mask layer prior to the forming of the first photoresist pattern and forming a second organic anti-reflective layer on the second hard mask layer prior to the forming of the second photoresist pattern.

These embodiments may further include surface-treating the first photoresist pattern to reduce a LWR of the first photoresist pattern between the forming of the first photoresist pattern and the forming of the mask material layer and surface-treating the second photoresist pattern to reduce a LWR of the second photoresist pattern between the forming of the second photoresist pattern and the etching of the partially exposed portion of the second hard mask layer.

These embodiments may further include removing the first photoresist pattern between the etching of the mask material and the etching of the portion of the second hard mask layer, removing the second photoresist pattern between the etching of the partially exposed portion of the second hard mask layer and the etching of the first hard mask layer, removing the second hard mask pattern between the etching of the first hard mask layer and the etching of the insulating layer and removing the first hard mask pattern after the etching of the insulating layer.

### BRIEF DESCRIPTION OF THE DRAWINGS

The above and other features and advantages of the present invention will become more apparent by describing in detail exemplary embodiments thereof with reference to the attached drawings in which:

FIGS. 1A through 1F are cross-sectional views for explaining a conventional method of forming a fine pattern in a semiconductor device;

FIGS. 2A through 2H are cross-sectional views for explaining methods of forming a fine pattern in an integrated circuit substrate according to some embodiments of the present invention;

FIGS. 3A, 4A, 5A to 14A are plan views for explaining methods of manufacturing integrated circuits according to other embodiments of the present invention;

FIGS. 3B, 4B, 5B to 14B are cross-sectional views taken along lines B-B of FIGS. 3A, 4A, 5A to 14A, respectively; and

FIGS. 3C, 4C, 5C to 14C are cross-sectional views taken along lines C-C of FIGS. 3A, 4A, 5A to 14A, respectively.

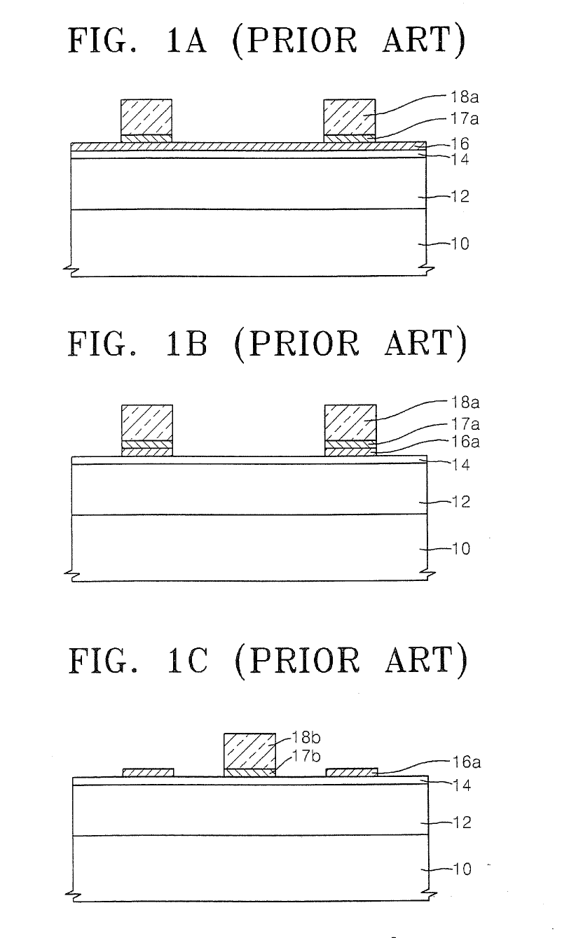

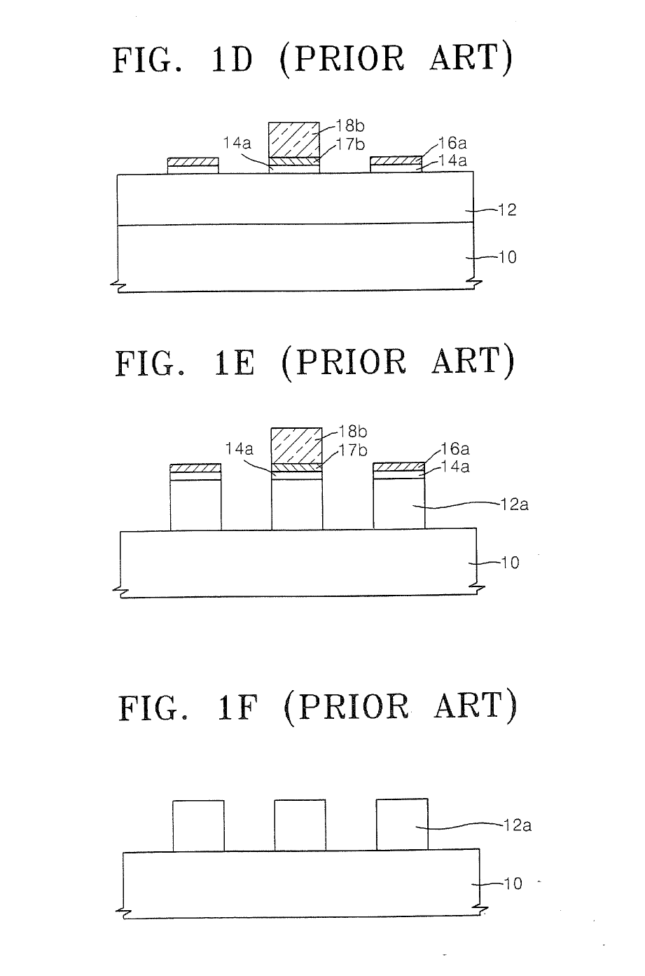

### DETAILED DESCRIPTION OF THE INVENTION

The invention will be described more fully hereinafter with reference to the accompanying drawings, in which example embodiments of the invention are shown. This invention may, however, be embodied in many different forms and should not be construed as limited to the example embodiments set forth herein. Rather, the disclosed embodiments are provided so that this disclosure will be thorough and complete, and will fully convey the scope of the invention to those skilled in the art. In the drawings, the size and relative sizes of layers and regions may be exaggerated for clarity. Like numbers refer to like elements throughout.

It will be understood that when an element or layer is referred to as being “on”, “connected to” and/or “coupled to” another element or layer, it can be directly on, connected or coupled to the other element or layer or intervening elements or layers may be present. In contrast, when an element is referred to as being “directly on,” “directly connected to” and/or “directly coupled to” another element or layer, there are no intervening elements or layers present. As used herein, the term “and/or” may include any and all combinations of one or more of the associated listed items.

It will be understood that, although the terms first, second, third, etc., may be used herein to describe various elements, components, regions, layers and/or sections, these elements, components, regions, layers and/or sections should not be limited by these terms. These terms may be used to distinguish one element, component, region, layer and/or section from another region, layer and/or section. For example, a first element, component, region, layer and/or section discussed below could be termed a second element, component, region, layer and/or section without departing from the teachings of the present invention.

Spatially relative terms, such as “below”, “lower”, “above”, “upper” and the like, may be used herein for ease of description to describe an element and/or a feature's relationship to another element(s) and/or feature(s) as illustrated in the figures. It will be understood that the spatially relative terms are intended to encompass different orientations of the device in use or operation in addition to the orientation depicted in the figures. For example, if the device in the figures is turned over, elements described as “below” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly. Moreover, the term “beneath” also indicates a relationship of one layer or region to another layer or region relative to the substrate, as illustrated in the figures.

The terminology used herein is for the purpose of describing particular embodiments only and is not intended to be limiting of the invention. As used herein, the singular terms “a”, “an” and “the” are intended to include the plural forms as well, unless the context clearly indicates otherwise. It will be further understood that the terms “comprises,” “comprising,” “includes” and/or “including” when used in this specification, specify the presence of stated features, integers, steps, operations, elements, and/or components, but do not preclude the presence or addition of one or more other features, integers, steps, operations, elements, components, and/or groups thereof.

Example embodiments of the invention are described herein with reference to cross-section illustrations that are schematic illustrations of idealized embodiments (and intermediate structures) of the invention. As such, variations from the shapes of the illustrations as a result, for example, of manufacturing techniques and/or tolerances, may be expected. Thus, the disclosed example embodiments of the invention should not be construed as limited to the particular shapes of regions illustrated herein unless expressly so defined herein, but are to include deviations in shapes that result, for example, from manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the figures are schematic in nature and their shapes are not intended to illustrate the actual shape of a region of a device and are not intended to limit the scope of the invention, unless expressly so defined herein.

Unless otherwise defined, all terms (including technical and scientific terms) used herein have the same meaning as commonly understood by one of ordinary skill in the art to which this invention belongs. It will be further understood that terms, such as those defined in commonly used dictionaries, should be interpreted as having a meaning that is consistent with their meaning in the context of the relevant art and the present disclosure, and will not be interpreted in an idealized or overly formal sense unless expressly so defined herein.

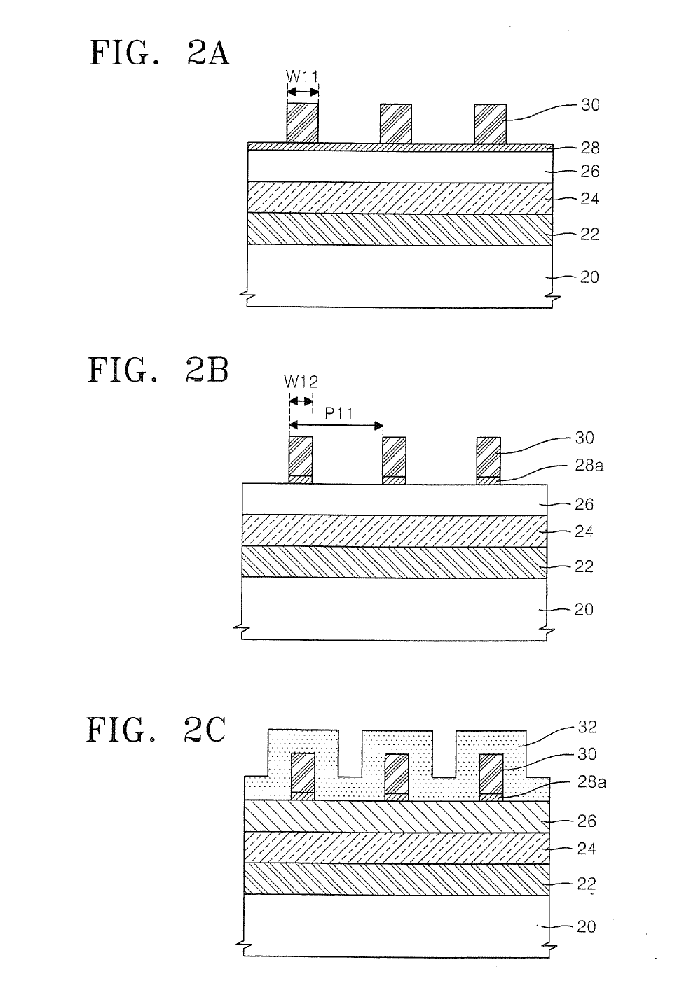

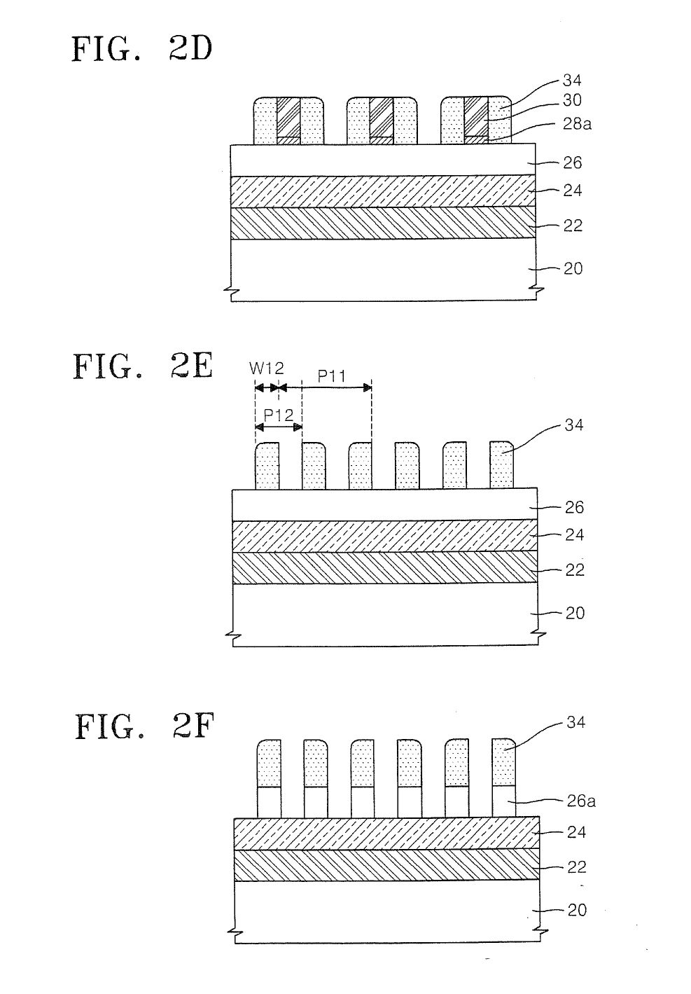

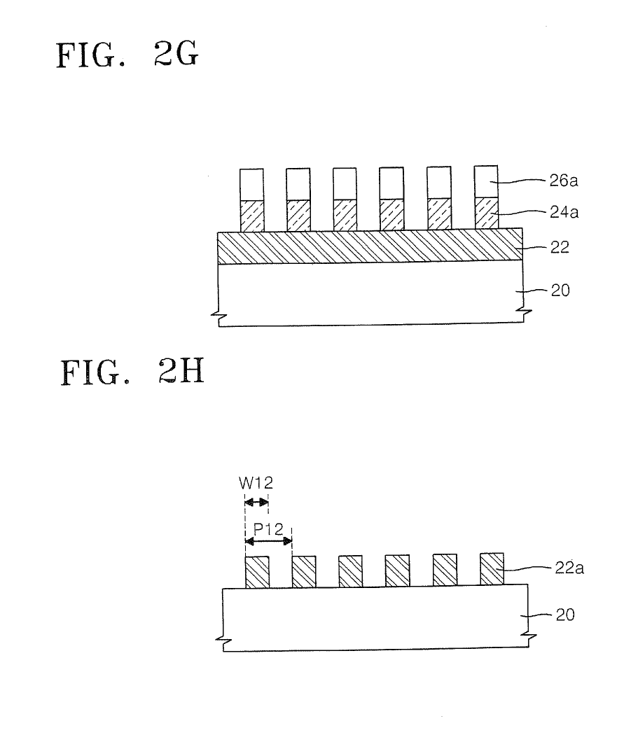

FIGS. 2A through 2H are cross-sectional views for explaining methods of forming fine patterns in an integrated circuit substrate according to some embodiments of the present invention. Referring to FIG. 2A, a lower layer 22 is formed on an integrated circuit substrate, such as a semiconductor substrate 20. The integrated circuit substrate may comprise a single element and/or compound semiconductor substrate, such as a monocrystalline silicon substrate, and may include one or more epitaxial and/or other conductive/insulating layers thereon. The lower layer 22 may include a conductive layer and/or an insulating layer. A first hard mask layer 24 is formed on the lower layer 22. The first hard mask layer 24 may be formed by coating spin-on-carbon (SOC) and/or bottom photoresist on the lower layer 22 to a thickness of about 2300 Å to about 2800 Å. A second hard mask layer 26 is formed on the first hard mask layer 24. The second hard mask layer 26 may include a material having an etch selectivity with respect to the first hard mask layer 24. The second hard mask layer 26 may include a silicon-containing layer. For example, the second hard mask layer 26 may include a silicon anti-reflective coating (ARC) layer. The second hard mask layer 26 may be formed of silicon ARC layer to a thickness of about 600 Å to about 800 Å. An anti-reflective layer 28 is formed on the second hard mask layer 26. The anti-reflective layer 28 may include an organic anti-reflective layer. The anti-reflective layer 28 may have a thickness ranging from about 270 Å to about 330 Å. A photoresist layer is formed on the anti-reflective layer 28 to a thickness of about 1000 Å to about 1400 Å. A photoresist pattern 30 is formed by exposing and developing the photoresist layer using a mask (not shown). The photoresist pattern 30 has a first line width W11.

Referring to FIG. 2B, the photoresist pattern 30 is trimmed using O₂ plasma. After the trimming, the photoresist pattern 30 has a second line width W12 (smaller than the first line width W11) and a first pitch P11. For example, when forming a fine pattern having a line width of about 30 nm and a pitch of about 60 nm, the photoresist pattern 30 may be formed to a first line width W11 of about 50 nm by patterning, and then may be trimmed to a second line width W12 of about 30 nm. The second line width W12 of the photoresist pattern 30 can be about 30 nm in this way. The first pitch P11 of the photoresist pattern 30 is about 120 nm (this may be reduced to about 60 nm in a later process). To reduce the line width roughness (LWR) of the photoresist pattern 30, a surface treatment can be performed between the patterning and trimming operations. The surface treatment can be performed by various methods such as HBr plasma curing, ultraviolet curing, and/or electron beam curing. The anti-reflective layer 28 is etched using the photoresist pattern 30 to form an anti-reflective pattern 28a.

Referring to FIG. 2C, a mask material layer 32 is formed on the second hard mask layer 26, the photoresist pattern 30, and the anti-reflective pattern 28a by atomic layer deposition (ALD). As shown in FIG. 2C, the mask material layer 32 is atomic layer deposited on the photoresist pattern 30, also referred to herein as a sacrificial pattern, including on the tops and the side walls thereof, and on the integrated circuit substrate (for example, directly on the second hard mask layer 26) therebetween. Since the process temperature of the ALD used for forming the mask material layer 32 may be relatively low, the photoresist pattern 30 can be used as a sacrificial layer for forming a mask pattern. That is, since the photoresist pattern 30 formed by exposing and developing can be used as a sacrificial layer, the process of forming the fine pattern can be simplified. The mask material layer 32 may include an ALD nitride layer. The thickness of the mask material layer 32 may be determined depending on the desired line width of the fine pattern to be formed. The mask material layer 32 may be formed to a thickness of about 50 Å to about 700 Å by ALD in a low temperature range from about 30° C. to about 130° C. The mask material layer 32 may be harder than the second hard mask layer 26. In this case, when the second hard mask layer 26 is etched using the mask material layer 32 to form a second hard mask pattern, the second hard mask pattern can have a low LWR since the hard mask material layer 32 is used to etch the relatively soft second hard mask layer 26. In these embodiments, the mask material layer 32 may include a nitride layer harder than an oxide layer or a silicon-containing layer of the second hard mask layer 26.

Referring to FIG. 2D, the mask material layer 32 is etched back until the photoresist pattern 30 is exposed, thereby forming a mask pattern 34 on side walls of the photoresist pattern 30 and the anti-reflective pattern 28a. Referring to FIG. 2E, the photoresist pattern 30 and the anti-reflective pattern 28a are removed, for example using O₂ plasma. The mask pattern 34 is used as a mask for patterning the second hard mask layer 26. The mask pattern 34 has a second line width W12 and a second pitch P12. The second pitch P12 is half a first pitch P11 in some embodiments. Therefore, when the second line width W12 and the first pitch P11 are about 30 nm and about 120 nm, the final line width W12 and pitch P12 of the mask pattern 34 is about 30 nm and almost 60 nm, respectively.

Referring to FIG. 2F, the second hard mask layer 26 is etched using the mask pattern 34 as an etch mask to form a second hard mask pattern 26a. Referring to FIG. 2G, the mask pattern 34 is removed. The first hard mask layer 24 is etched using the second hard mask pattern 26a as an etch mask to form a first hard mask pattern 24a. The first hard mask layer 24 also can be etched without removing the mask pattern 34. Referring to FIG. 2H, the second hard mask pattern 26a is removed. The lower layer 22 is etched using the first hard mask pattern 24a to form a fine pattern 22a. The fine pattern 22a has the same line width and pitch as the second line width W12 and the second pitch P12. The first hard mask pattern 24a is removed.

In other embodiments of the present invention, the anti-reflective layer 28 may be not formed between the second hard mask layer 26 and the photoresist pattern 30. Further, the first hard mask layer 24 can be formed of an amorphous carbon layer (ACL). In this case, the second hard mask layer 26 can be formed of a thin oxide layer having a thickness of about 300 Å to about 600 Å. The thin oxide layer may include a polyethylene (PE)-oxide layer, a middle temperature oxide (MTO) layer and/or an ALD oxide layer.

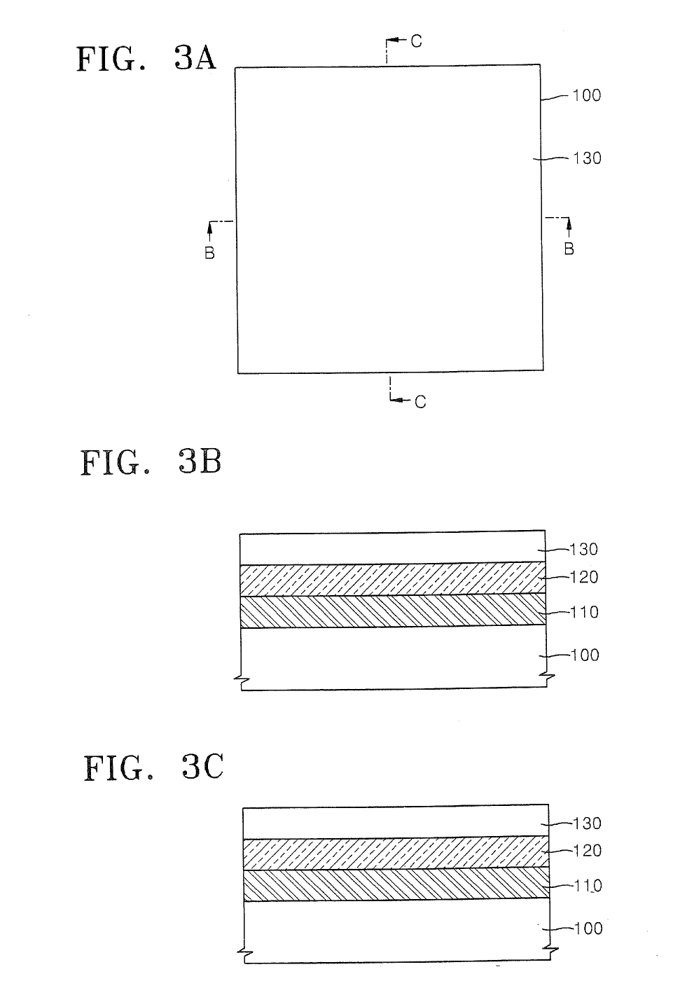

FIGS. 3A, 3B and 3C through 14A, 14B, and 14C are views for explaining methods of manufacturing integrated circuit devices using fine pattern forming methods depicted in FIGS. 2A through 2H, according to other embodiments of the present invention. FIGS. 3A, 4A, 5A to 14A are plan views for explaining methods of manufacturing integrated circuit devices according to these other embodiments of the present invention, FIGS. 3B, 4B, 5B to 14B are cross-sectional views taken along lines B-B of FIGS. 3A, 4A, 5A to 14A, respectively, and FIGS. 3C, 4C, 5C to 14C are cross-sectional views taken along lines C-C of FIGS. 3A, 4A, 5A to 14A, respectively.

Referring to FIGS. 3A, 3B, and 3C, an interlayer insulation layer 110 in which contact holes are to be formed is formed on an integrated circuit substrate, such as a semiconductor substrate 100. The integrated circuit substrate may comprise a single element and/or compound semiconductor substrate, such as a monocrystalline silicon substrate, and may include one or more epitaxial and/or other conductive/insulating layers thereon. A first hard mask layer 120 is formed on the interlayer insulation layer 110, and a second hard mask layer 130 is formed on the first hard mask layer 120. The second hard mask layer 130 includes a material having an etch selectivity with respect to the first hard mask layer 120. For example, the first hard mask layer 120 can be formed by depositing amorphous carbon layer to a thickness of about 1300 Å to about 1700 Å, and the second hard mask layer 130 may be formed by depositing an oxide layer (e.g., a PE oxide layer) to a thickness of about 900 Å to about 1100 Å. Further, the first hard mask layer 120 may include an SOC layer and/or a bottom photoresist layer, and the second hard mask layer 130 may include a silicon-containing layer such as a Si ARC layer and/or a spin-on-glass (SOG) layer.

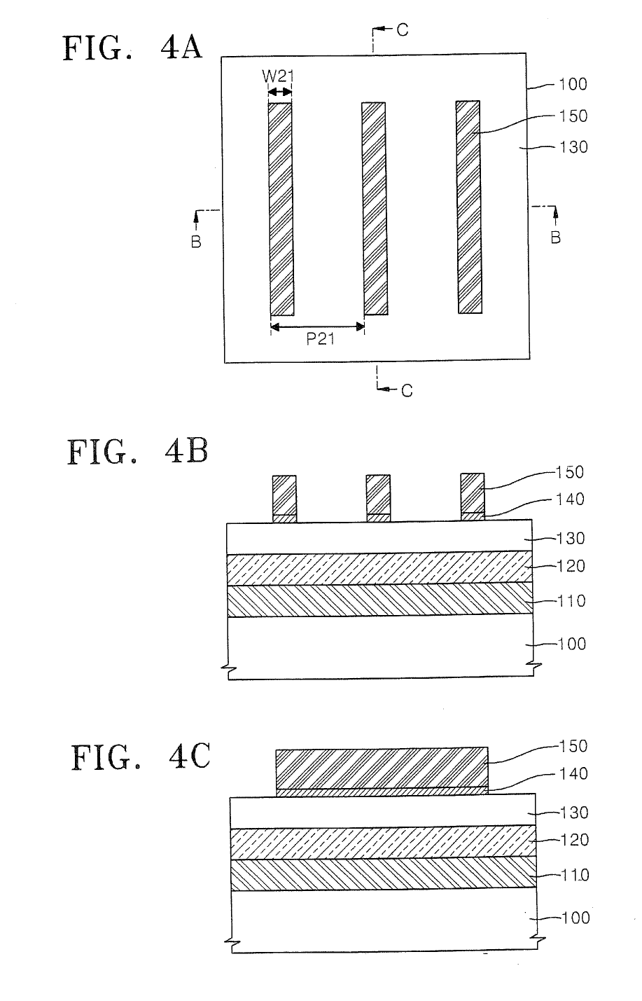

Referring to FIGS. 4A, 4B, and 4C, a first anti-reflective layer, such as an organic anti-reflective layer, is formed on the second hard mask layer 130 to a thickness of about 270 Å to about 330 Å. A first photoresist layer is coated on the first anti-reflective layer to a thickness of about 1000 Å to about 1400 Å. The first photoresist layer is patterned by exposing and developing to form a first photoresist pattern 150. The first photoresist pattern 150 can be surface-treated to reduce the LWR of the first photoresist pattern 150. The surface treatment of the first photoresist pattern 150 can be performed using HBr plasma treating, UV curing, electron beam curing, etc. After that, a trimming process may be performed using O₂ plasma. The first photoresist pattern 150 has a first line width W21 and a first pitch P21. The first photoresist pattern 150 may be first patterned to a line width larger than the first line width W21, and then may be trimmed to the first line width W21. The first line width of the photoresist pattern 150 is determined by a minor critical dimension (CD) defined in a transverse direction of contact holes to be formed. The first anti-reflective layer is etched using the first photoresist pattern 150 as an etch mask to form a first anti-reflective pattern 140.

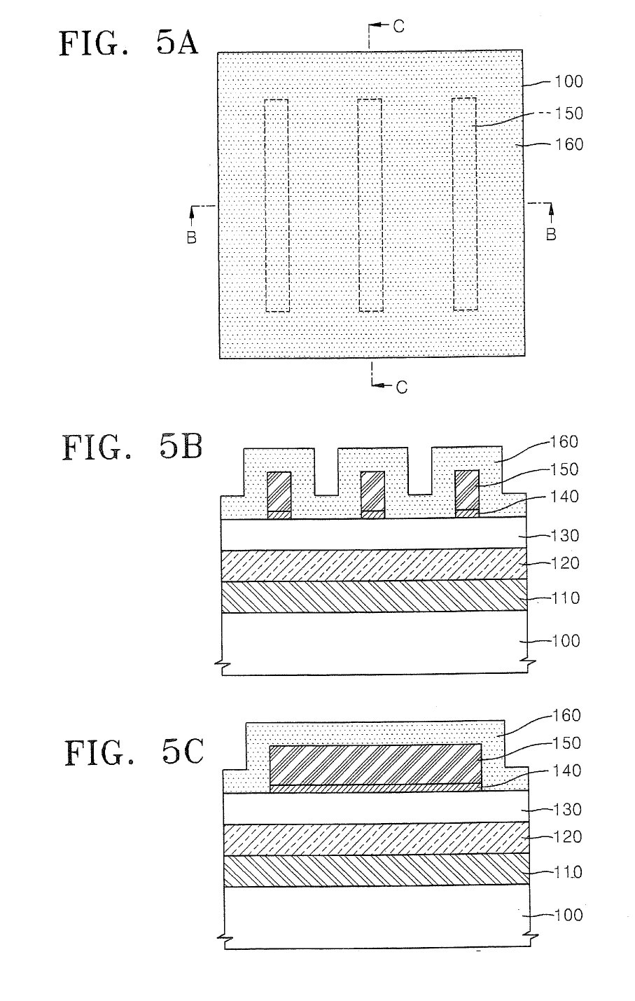

Referring to FIGS. 5A, 5B, and 5C, a mask material layer 160 is formed on the first photoresist pattern 150, the first anti-reflective pattern 140, and the second hard mask layer 130 by ALD at a low temperature range from about 30° C. to about 130° C. The thickness of the mask material layer 160 may be determined according to the line width of a mask pattern to be formed. The mask material layer 160 may be deposited to a thickness of about 50 Å to about 700 Å. The mask material layer 160 may include a material harder than the second hard mask layer 130. In this case, when the second hard mask layer 130 is etched using the mask material layer 160 to form a second hard mask pattern, the second hard mask pattern can have a low LWR since the hard mask material layer 160 is used to etch the relatively soft second hard mask layer 130. In some embodiments, the mask material layer 160 may include a nitride layer harder than an oxide layer or a silicon-containing layer of the second hard mask layer 130.

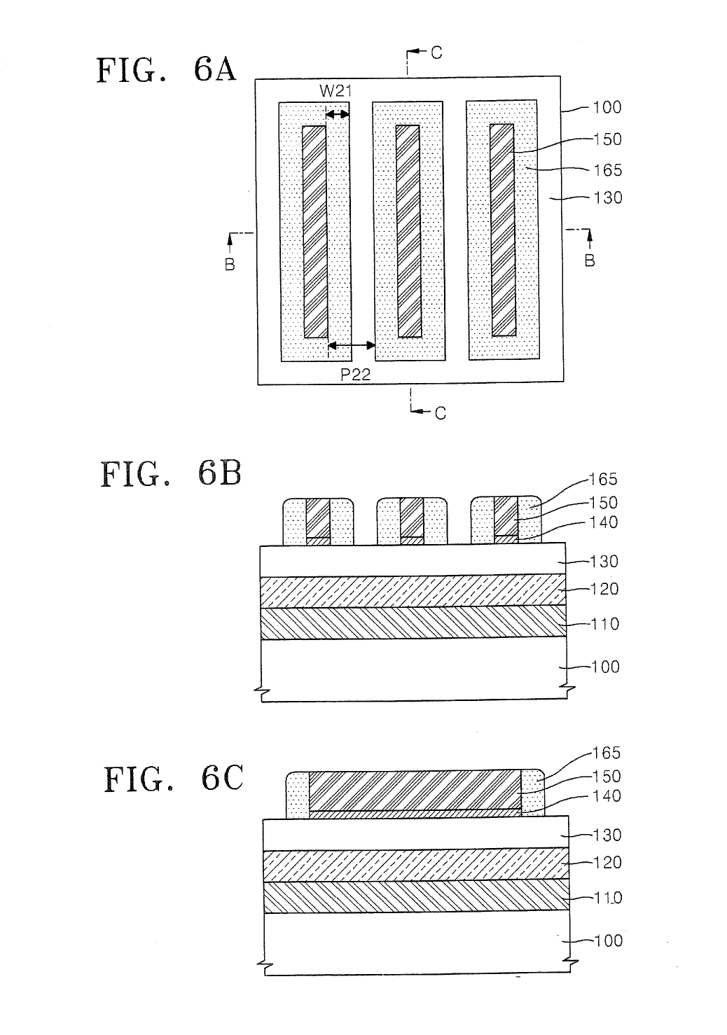

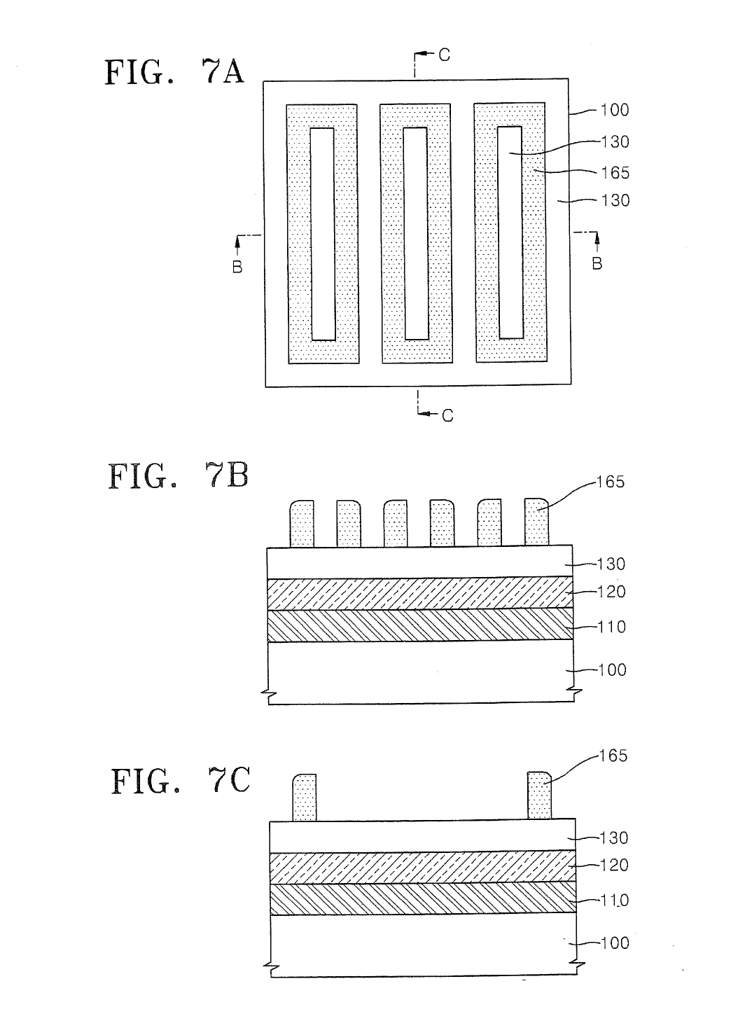

Referring to FIGS. 6A, 6B, and 6C, the mask material layer 160 is etched back until the first photoresist pattern 150 is exposed, thereby forming a mask pattern 165 on side walls of the photoresist pattern 150 and on the first anti-reflective pattern 140. In some embodiments, the mask pattern 165 has substantially the same line width as the first line width 21 of the first photoresist pattern 150. Further, the mask pattern 165 has a second pitch P22 in the direction of link B-B of FIG. 6A (in a transverse direction of contact holes to be formed later). The second pitch P22 is less than, and in some embodiments is half, the first pitch P21 of the photoresist pattern 150. Moreover, in some embodiments, instead of forming the mask pattern 165 on all the side surfaces of the first photoresist pattern 150, the mask pattern 165 can be formed only on two opposing sides of the first photoresist pattern 150 in the form of a line/space pattern. Referring to FIGS. 7A, 7B, and 7C, the first photoresist pattern 150 and the first anti-reflective pattern 140 are removed using O₂ plasma.

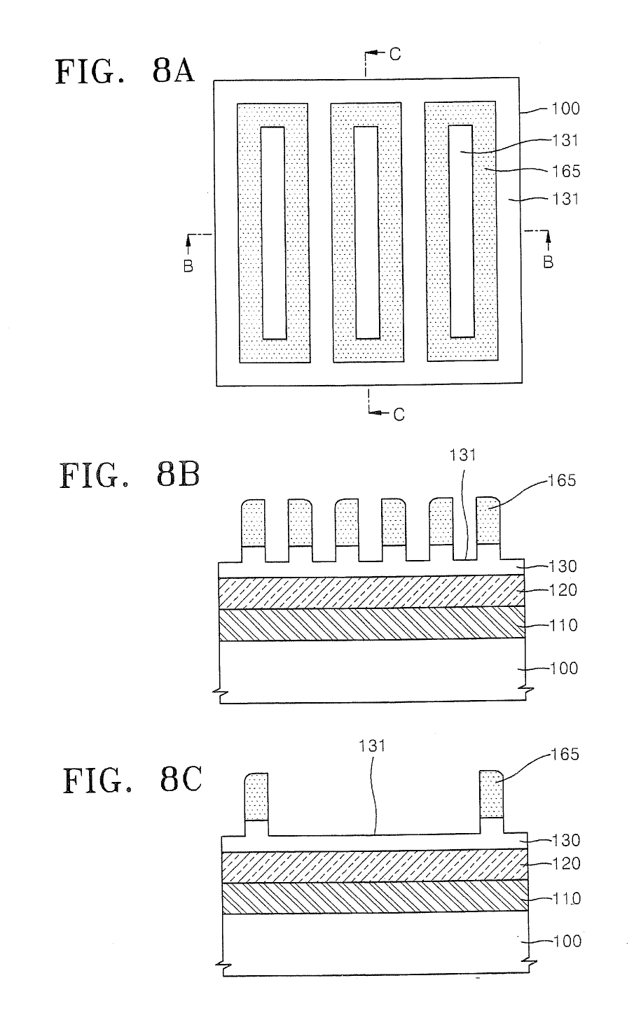

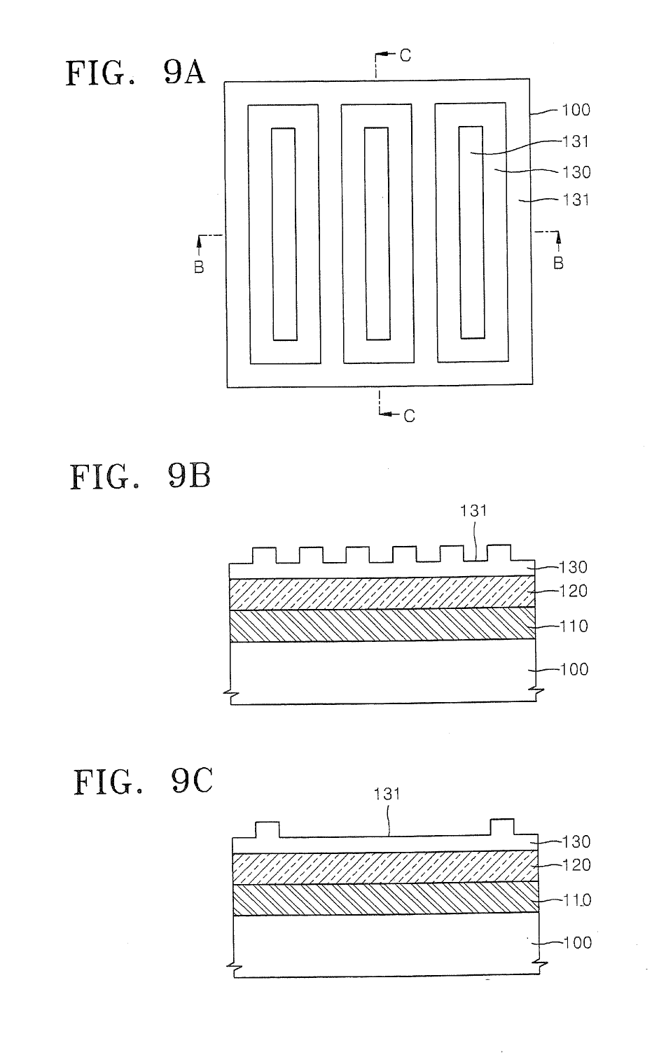

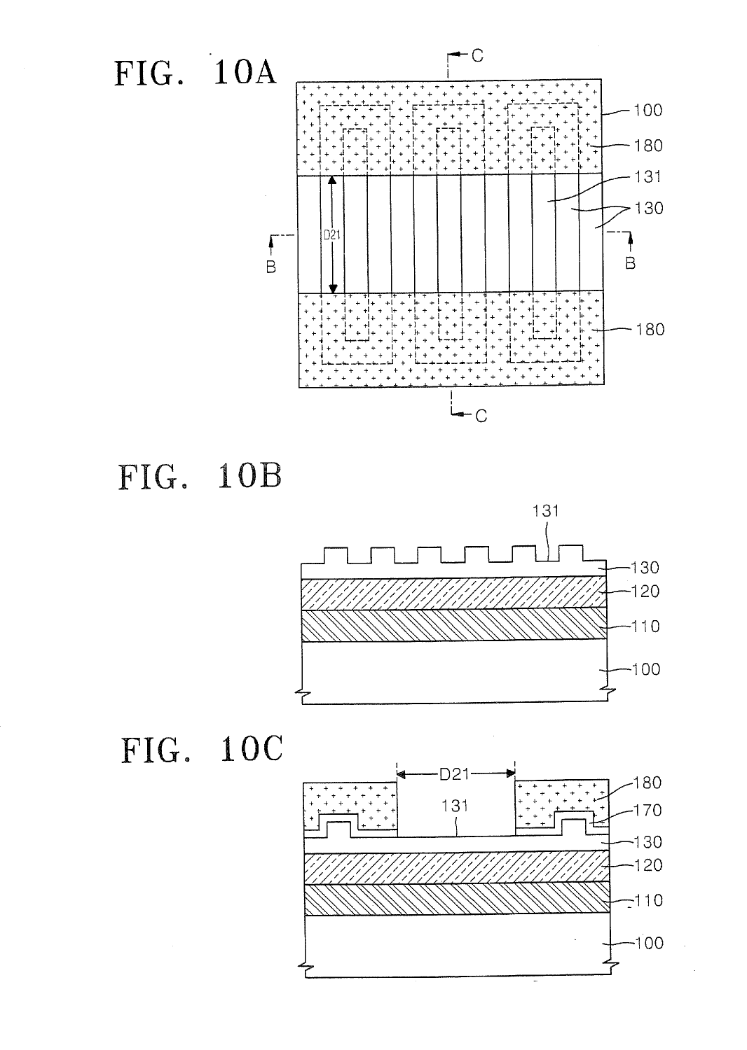

Referring to FIGS. 8A, 8B, and 8C, the second hard mask layer 130 is partially etched using the mask pattern 165 as an etch mask. For example, the second hard mask layer 130 is partially removed at a constant thickness of about 450 Å to about 550 Å. Contact holes will be formed at the first etched portions 131 of the second hard mask layer 130. Referring to FIGS. 9A, 9B, and 9C, the mask pattern 165 is removed by wet etching. Referring to FIGS. 10A, 10B, and 10C, a second anti-reflective layer and a second photoresist layer are sequentially formed on the semiconductor substrate 100 and are patterned to form a second anti-reflective pattern 170 and a second photoresist pattern 180. The second hard mask layer 130 is partially exposed by an opening formed in the second anti-reflective pattern 170 and the second photoresist pattern 180. That is, the first etched portions 131 of the second hard mask layer 130 are partially exposed by the opening formed in the second anti-reflective pattern 170 and the second photoresist pattern 180. The opening formed in the second anti-reflective pattern 170 and the second photoresist pattern 180 has a dimension D21 that can be determined by a major CD defined in a longitudinal direction (the direction of line C-C) of contact holes to be formed later. After the second photoresist pattern 180 is formed, a trimming process and/or a surface treatment process can be performed.

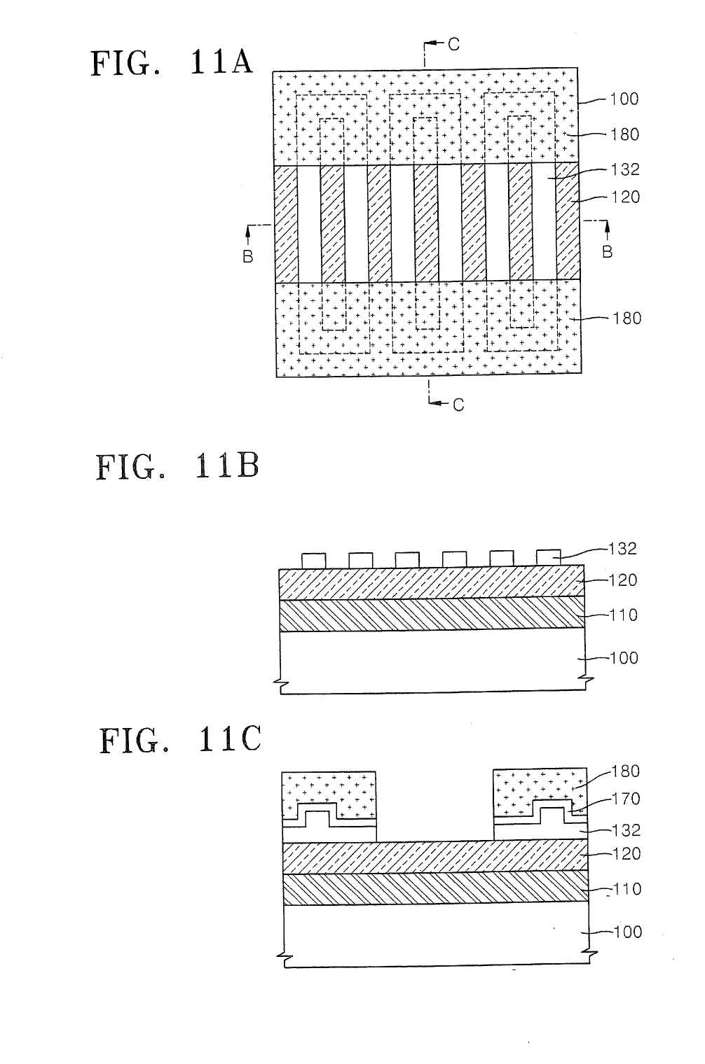

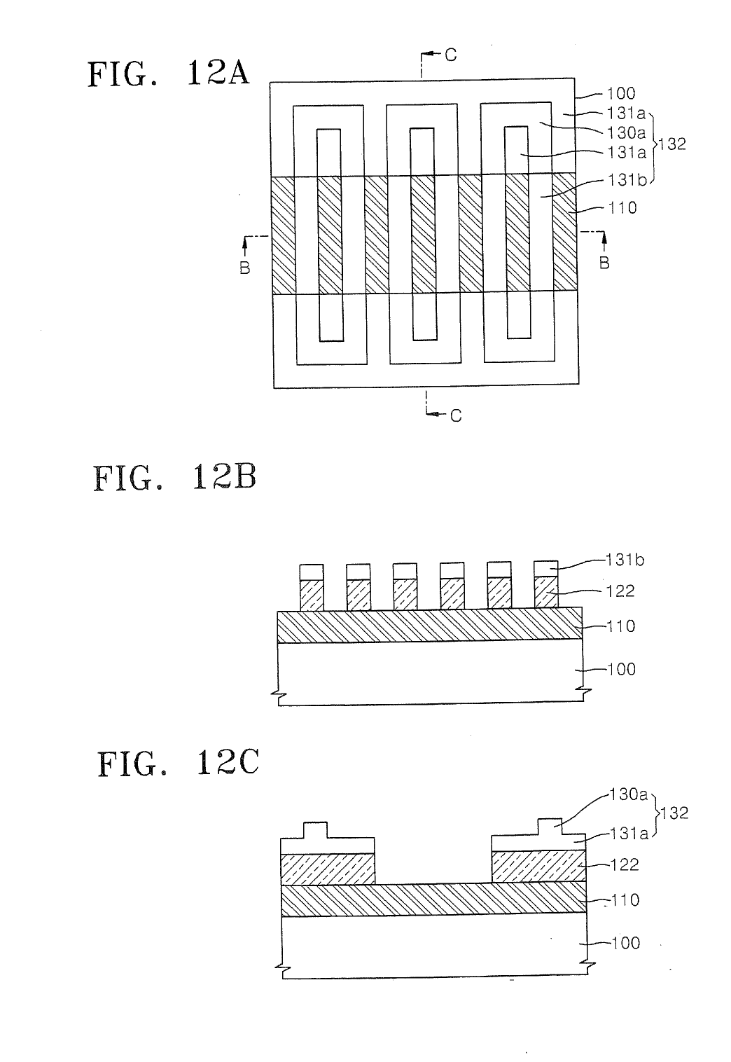

Referring to FIGS. 11A, 11B, and 11C, the exposed portion of the second hard mask layer 130 is etched using the second photoresist pattern 180 as an etch mask to form a second hard mask pattern 132. Here, the exposed portion of the first etched portions 131 of the second hard mask layer 130 are completely removed, and thus the first hard mask layer 120 is exposed. Referring to FIGS. 12A, 12B, and 12C, the second anti-reflective pattern 170 and the second photoresist pattern 180 are removed by O₂-plasma treatment. Here, reference numeral 130a denotes portions of the second hard mask pattern 132 that are not etched during first and second etching processes performed on the second hard mask layer 130, reference numeral 131a denotes portions of the second hard mask pattern 132 that are etched only through the first etching process, and reference numeral 131b denotes portions of the second hard mask pattern 132 that are etched both through the first and second etch processes. After the second hard mask pattern 132 is formed, the first hard mask layer 120 is etched using the second hard mask pattern 132 as an etch mask to form a first hard mask pattern 122.

In other embodiments of the present invention, the mask pattern 165 (formed of an ALD nitride layer) may be not removed in the process illustrated in FIGS. 9A, 9B, and 9C. In this case, the second anti-reflective pattern 170 and the second photoresist pattern 180 may be formed on the mask pattern 165 in the process illustrated in FIGS. 10A, 10B, and 10C, and the second hard mask layer 130 may be etched using the second photoresist pattern 180 and the mask pattern 165 as etch masks to form the second hard mask pattern 132 in the process illustrated in FIGS. 11A, 11B, and 11C. Further, if where the second anti-reflective pattern 170 and the second photoresist pattern 180 are not removed, the first hard mask layer 120 can be etched using the second hard mask pattern 132 as an etch mask to form the first hard mask pattern 122. Furthermore, the first anti-reflective pattern 140 and/or the second anti-reflective pattern 170 may not be formed.

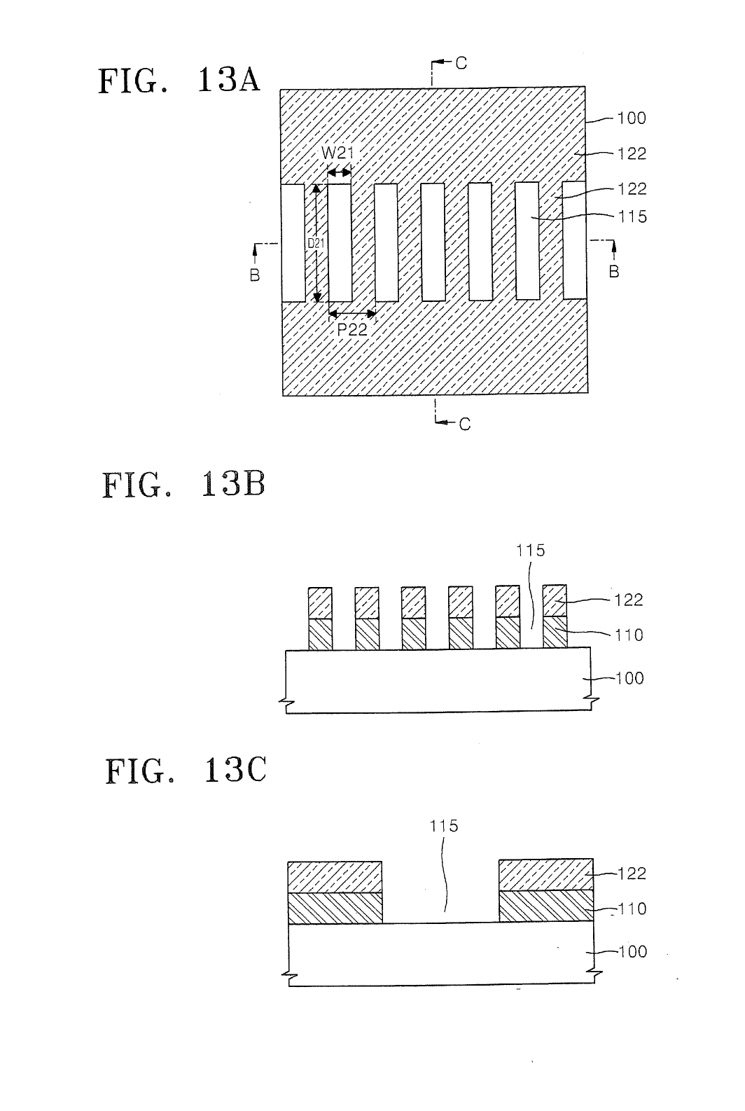

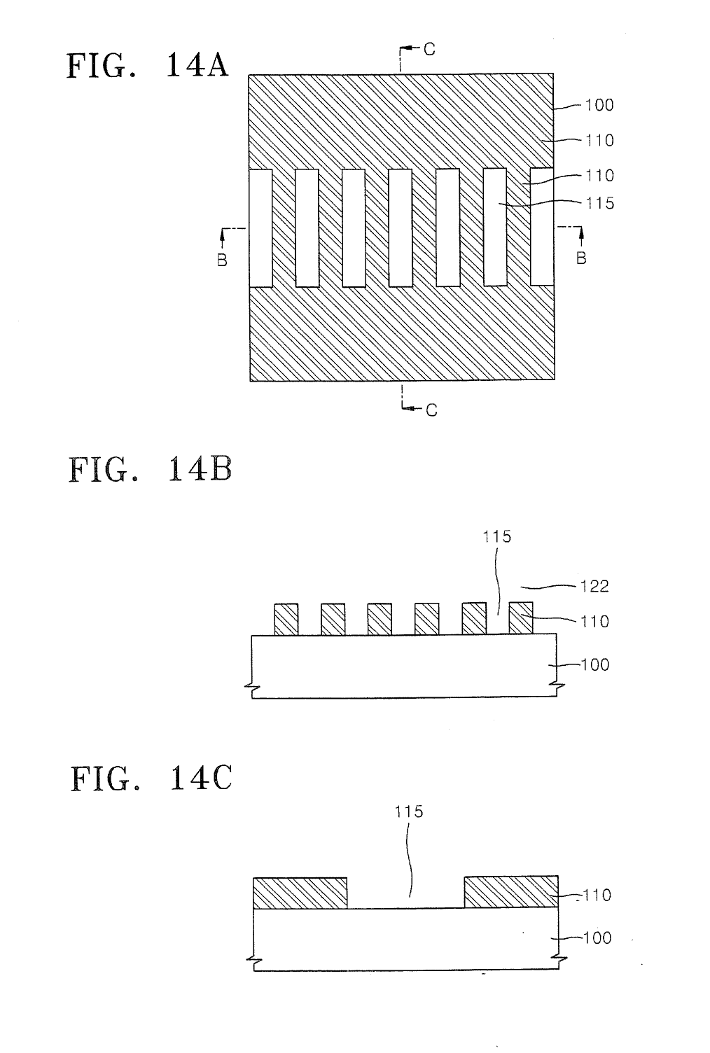

Referring to FIGS. 13A, 13B, and 13C, the second hard mask pattern 132 is removed, and then the interlayer insulation layer 110 is etched using the first hard mask pattern 122 as an etch mask to form contact holes 115. The contact holes 115 can have a minor CD in the direction of line B-B that is substantially the same as the first line width W21, and a major CD in the direction of line C-C that is substantially the same as the dimension D21. Further, the contact holes 115 can have substantially the same pitch as the second pitch P22. Referring to FIGS. 14A, 14B, and 14C, the first hard mask pattern 122 is removed. In other embodiments of the present invention, the second hard mask pattern 132 may not be removed in the process illustrated in FIGS. 13A, 13B, and 13C, and in this state, the interlayer insulation layer 110 can be etched to form the contact holes 115.

As described above, according to some embodiments of the present invention, ALD silicon nitride (SiN), which can be processed at a low temperature, is used as the mask material, so that the mask pattern can be formed only by patterning the photoresist layer without depositing and patterning an additional sacrificial oxide layer. Therefore, the process can be simple. Furthermore, according to some embodiments of the present invention, patterning failure caused by remaining portions of an anti-reflective layer can be reduced/eliminated. In addition, according to some embodiments of the present invention, a finer pattern can be formed using a conventional exposure device. As a result, integrated circuit devices having an improved fine pattern can be manufactured with improved alignment and LWR.

In the drawings and specification, there have been disclosed embodiments of the invention and, although specific terms are employed, they are used in a generic and descriptive sense only and not for purposes of limitation, the scope of the invention being set forth in the following claims.

What is claimed is:

1. A method of forming a fine pattern in an integrated circuit substrate, the method comprising:
sequentially forming a first hard mask layer and a second hard mask layer on the integrated circuit substrate, the second hard mask layer having an etch selectivity with respect to the first hard mask layer;
forming a photoresist pattern on the second hard mask layer, the photoresist pattern having a first line width and a first pitch;
forming a mask material layer on the photoresist pattern and the second hard mask layer by atomic layer deposition, the mask material layer including a material harder than the second hard mask layer;
etching the mask material layer until the photoresist pattern is exposed in order to form a mask pattern on side walls of the photoresist pattern, the mask pattern having a second pitch that is less than the first pitch;
removing the photoresist pattern;
etching the second hard mask layer using the mask pattern to form a second hard mask pattern;
etching the first hard mask layer using the second hard mask pattern as a mask to form a first hard mask pattern; and
etching the integrated circuit substrate using the first hard mask pattern as a mask to form a fine pattern having same pitch as the second pitch.

2. The method of claim 1, further comprising forming an organic anti-reflective layer on the second hard mask layer prior to the forming of the photoresist pattern.

3. The method of claim 1, wherein the forming of the photoresist pattern comprises:
coating a photoresist layer on the second hard mask layer;
exposing and developing the photoresist layer to form the photoresist pattern with a second line width larger than the first line width; and
trimming the photoresist pattern to the first line width using O₂ plasma.

4. The method of claim 1, further comprising surface-treating the photoresist pattern to reduce a line width roughness of the photoresist pattern prior to the forming of the mask material layer.

5. The method of claim 1, wherein the first hard mask layer comprises a spin-on-carbon layer and/or a bottom photoresist layer, and the second hard mask layer comprises a silicon-containing layer.

6. The method of claim 1, wherein the first hard mask layer comprises an amorphous carbon layer, and the second hard mask layer comprises an oxide layer.

7. The method of claim 1, wherein the mask material layer comprises a nitride layer formed by atomic layer deposition in a temperature range from about 30° C. to about 130° C.

8. The method of claim 1, further comprising:
removing the mask pattern between the etching of the second hard mask layer and the etching of the first hard mask layer;
removing the second hard mask pattern between the etching of the first hard mask layer and the etching of the integrated circuit substrate; and
removing the first hard mask pattern after the etching of the integrated circuit substrate.

9. A method of forming a fine pattern in an integrated circuit substrate, the method comprising:
forming an insulating layer on the integrated circuit substrate;
sequentially forming a first hard mask layer and a second hard mask layer on the insulating layer, the second hard mask layer having an etch selectivity with respect to the first hard mask layer;
forming a first photoresist pattern on the second hard mask layer, the first photoresist pattern having a first line width and a first pitch;
forming a mask material layer on the first photoresist pattern and the second hard mask layer by atomic layer deposition, the mask material layer including a material harder than the second hard mask layer;
etching the mask material layer until the first photoresist pattern is exposed in order to form a mask pattern on side walls of the first photoresist pattern, the mask pattern having a second pitch that is less than the first pitch;
etching a portion of the second hard mask layer using the mask pattern;
forming a second photoresist pattern on the second hard mask layer, the second photoresist pattern partially exposing the etched portion of the second hard mask layer;
etching the partially exposed portion of the second hard mask layer using the second photoresist pattern until the first hard mask layer is exposed, so as to form a second hard mask pattern;
etching the first hard mask layer using the second hard mask pattern as a mask to form a first hard mask pattern; and
etching the insulating layer using the first hard mask pattern as a mask to form a contact hole.

10. The method of claim 9, further comprising removing the mask pattern between the etching of the portion of the second hard mask layer and the forming of the second photoresist pattern.

11. The method of claim 9, further comprising:
forming a first organic anti-reflective layer on the second hard mask layer prior to the forming of the first photoresist pattern; and
forming a second organic anti-reflective layer on the second hard mask layer prior to the forming of the second photoresist pattern.

12. The method of claim 9, wherein the forming of the first photoresist pattern comprises:
coating a photoresist layer on the second hard mask layer;
exposing and developing the photoresist layer to form the first photoresist pattern with a second line width larger than the first line width; and
trimming the first photoresist pattern to the first line width using O₂ plasma.

13. The method of claim 9, further comprising:
surface-treating the first photoresist pattern to reduce a line width roughness of the first photoresist pattern between the forming of the first photoresist pattern and the forming of the mask material layer; and
surface-treating the second photoresist pattern to reduce a line width roughness of the second photoresist pattern between the forming of the second photoresist pattern and the etching of the partially exposed portion of the second hard mask layer.

14. The method of claim 9, wherein the first hard mask layer comprises a spin-on-carbon layer and/or a bottom photoresist layer, and the second hard mask layer comprises a silicon-containing layer.

15. The method of claim 9, wherein the first hard mask layer comprises an amorphous carbon layer, and the second hard mask layer comprises an oxide layer.

16. The method of claim 9, wherein the mask material layer comprises a nitride layer formed by atomic layer deposition in a temperature range from about 30° C. to about 130° C.

17. The method of claim 9, further comprising:
removing the first photoresist pattern between the etching of the mask material and the etching of the portion of the second hard mask layer;
removing the second photoresist pattern between the etching of the partially exposed portion of the second hard mask layer and the etching of the first hard mask layer;
removing the second hard mask pattern between the etching of the first hard mask layer and the etching of the insulating layer; and
removing the first hard mask pattern after the etching of the insulating layer.

18. A method of forming a fine pattern in an integrated circuit substrate, the method comprising:
forming a sacrificial pattern on the integrated circuit substrate, the sacrificial pattern including tops and side walls;
atomic layer depositing a mask material layer on the sacrificial pattern, including on the tops and the side walls thereof and on the integrated circuit substrate therebetween;
etching the mask material layer that was atomic layer deposited to expose the tops and the integrated circuit substrate therebetween, such that a mask material pattern remains on the side walls;
removing the sacrificial pattern; and
etching the integrated circuit substrate through the mask material pattern that remains.

19. The method of claim 18 wherein atomic layer depositing a mask material layer comprises atomic layer depositing a nitride layer in a temperature range from about 30° C. to about 130° C.

20. The method of claim 19 wherein forming a sacrificial pattern on the integrated circuit substrate comprises forming a sacrificial photoresist pattern on the integrated circuit substrate.
